(19) United States
(12) Patent Application Publication
(10) Pub. No.: US 2010/0052799 A1
(43) Pub. Date: Mar. 4, 2010

(54) VOLTAGE CONTROLLED OSCILLATOR, MMIC, AND HIGH FREQUENCY WIRELESS DEVICE

(75) Inventors: Shinsuke Watanabe, Tokyo (JP); Seiki Goto, Tokyo (JP); Yoshihiro Tsukahara, Tokyo (JP); Ko Kanaya, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/473,317

(22) Filed: May 28, 2009

(30) Foreign Application Priority Data
Sep. 1, 2008 (JP) 2008-223274

(51) Int. Cl. H03L 7/00

(52) U.S. Cl. 331/34

(57) ABSTRACT

A voltage controlled oscillator having low phase noise and including: a variable resonator including a varactor and a control voltage terminal; and an open-end stub connected in parallel to the variable resonator, the open-end stub having a length shorter than or equal to an odd multiple of one quarter of a wavelength of a harmonic signal plus one sixteenth of the wavelength of the harmonic signal, and longer than or equal to an odd multiple of one quarter of the wavelength of the harmonic signal minus one sixteenth of the wavelength of the harmonic signal. In this structure, a high Q value is realized for a fundamental wave frequency. Fluctuation in a control voltage due to a harmonic signal is controlled.

### BACKGROUND OF THE INVENTION

1. Field of the Invention

The present invention relates to a voltage controlled oscillator, an MMIC, and a high frequency wireless device. In particular, the present invention relates to a voltage controlled oscillator, an MMIC, and a high frequency wireless device that work in a microwave or millimeter wave range.

2. Description of the Related Art

In conjunction with the widespread proliferation of high frequency wireless devices including a car-mounted radar device and a mobile phone, there has been a growing requirement for high performance of oscillators having output frequency of 1 GHz or higher. The oscillator is a circuit for generating oscillation of a high frequency electric signal inside the circuit so as to deliver the high frequency electric signal to the outside. In particular, an oscillator having a control voltage terminal for changing the output frequency is called a voltage controlled oscillator (VCO). The oscillator includes an active device such as a transistor for amplifying the high frequency electric signal and a resonator for oscillating a high frequency electric signal having a specific frequency. In order to realize a variable output function, the VCO includes a variable resonator having mainly a varactor (variable capacitor). A control voltage is applied to the varactor for changing capacitance of the varactor so that the output frequency can be changed.

As important characteristics of the VCO, there are phase noise and output frequency. The phase noise is an indicator of stability of the output frequency. When the high frequency wireless device is used for a radar device or a communication device, the phase noise affects its accuracy in measuring distances or its communication error rate. Therefore, it is desirable that the phase noise should be a lower value.

One of methods for controlling (or suppressing) the phase noise of the VCO is to improve a Q value of the resonator (an indicator of an energy amount that the resonator can store for an electric signal of a specific frequency). As an example of the method, there is a reported method in which a plurality of stubs are used for the resonator so as to make the resonator having a high Q value (see, for example, “A Low Phase Noise 19 GHz-band VCO using Two Different Frequency Resonators”, IEEE MTT-S Int. Microwave Symp. Digest, pp. 2189-2191, 2003).

Further, as another method for controlling (or suppressing) the phase noise of the VCO, there is a method of controlling a phenomenon that a voltage fluctuates at the terminal of a transistor on the resonator side in the VCO by using harmonic signals such as the second harmonic signal, the third harmonic signal, and so on (see, for example, “A Ka-Band Second Harmonic Oscillator with Optimized Harmonic Load”, IEICE technical report, Vol. 107, No. 355, pp. 29-32, November, 2007).

Although many methods for controlling the phase noise are proposed as described above, it is difficult to make a resonator having a high Q value in the VCO having an output frequency above 30 GHz. Therefore, it is impossible to obtain sufficiently low phase noise characteristics.

In addition, it is desirable that the VCO directly deliver a signal of the frequency to be handled by the high frequency wireless device. It is possible to use the VCO that delivers a signal of a frequency lower than the frequency handled by the wireless device together with a frequency multiplier, but it is not advantageous for cost reduction because the structure of the wireless device becomes complicated. In today's circumstances where high frequencies to be handled by wireless devices have become higher and higher, it is desired to improve the output frequency of the VCO.

As the output frequency is increased, the phase noise of the VCO is increased, in other words, deteriorated in principle. If the output frequency is increased up to a frequency in the millimeter wave band or higher (above 30 GHz), it is difficult to make a resonator having a high Q value. Therefore, it is impossible to make a VCO having sufficiently low phase noise characteristics.

In the method of using a plurality of resonators as described above in “A Low Phase Noise 19 GHz-band VCO using Two Different Frequency Resonators”, IEEE MTT-S Int. Microwave Symp. Digest, pp. 2189-2191, 2003, the Q value is improved only for a fundamental wave frequency, i.e., an oscillation frequency, and hence a circuit load for a harmonic frequency cannot be optimized. Further, in the method of controlling voltage fluctuations by using harmonic signals described above in “A Ka-Band Second Harmonic Oscillator with Optimized Harmonic Load”, IEICE technical report, Vol. 107, No. 355, pp. 29-32, November, 2007, only the circuit loads for the harmonic frequencies are taken into account, but the Q value for the fundamental wave frequency cannot be improved. Therefore, these methods have a problem in that sufficiently low phase noise characteristics cannot be obtained in the VCO having an output frequency above approximately 30 GHz in particular.

### SUMMARY OF THE INVENTION

The present invention has been created as a solution to the above-mentioned problem, and it is an object thereof to obtain a voltage controlled oscillator (VCO), a monolithic microwave integrated circuit (MMIC), and a high frequency wireless device that can realize low phase noise characteristics even at an output frequency in the microwave band (1 GHz or more) or the millimeter wave band (30 GHz or more).

The present invention provides a voltage controlled oscillator including: a variable resonator; and at least one open-end stub connected in parallel to the variable resonator, the at least one open-end stub having a length smaller than or equal to an odd multiple of one quarter of a wavelength of a harmonic signal plus one sixteenth of the wavelength of the harmonic signal and larger than or equal to an odd multiple of one quarter of the wavelength of the harmonic signal minus one sixteenth of the wavelength of the harmonic signal.

The present invention also provides a voltage controlled oscillator including: a variable resonator; and at least one short-end stub connected in parallel to the variable resonator, the at least one short-end stub having a length smaller than or equal to an integral multiple of a wavelength of a harmonic signal plus one sixteenth of the wavelength of the harmonic signal and larger than or equal to an integral multiple of the wavelength of the harmonic signal minus one sixteenth of the wavelength of the harmonic signal.

The present invention provides a voltage controlled oscillator including: a variable resonator; and at least one open-end stub connected in parallel to the variable resonator, the at least one open-end stub having a length smaller than or equal to an odd multiple of one quarter of a wavelength of a harmonic signal plus one sixteenth of the wavelength of the harmonic signal and larger than or equal to an odd multiple of one quarter of the wavelength of the harmonic signal minus one sixteenth of the wavelength of the harmonic signal. In addition, the present invention provides a voltage controlled oscillator including: a variable resonator; and at least one short-end stub connected in parallel to the variable resonator, the at least one short-end stub having a length smaller than or equal to an integral multiple of a wavelength of a harmonic signal plus one sixteenth of the wavelength of the harmonic signal and larger than or equal to an integral multiple of the wavelength of the harmonic signal minus one sixteenth of the wavelength of the harmonic signal. Thus, it is possible to realize low phase noise characteristics even at an output frequency in the microwave band (1 GHz or more) or the millimeter wave band (30 GHz or more).

### BRIEF DESCRIPTION OF THE DRAWINGS

In the accompanying drawings:

FIG. 1 is a structural diagram illustrating a structure of a voltage controlled oscillator to which an open-end stub is added having a line length of λ/4 for a second harmonic according to Embodiment 1 of the present invention;

FIG. 2 is a structural diagram illustrating a structure of a voltage controlled oscillator in which an short-end stub is disposed having a line length of λ for a second harmonic according to Embodiment 2 of the present invention;

FIG. 3 is an explanatory diagram illustrating a field intensity distribution of 38 GHz that is a fundamental wave signal according to Embodiment 2 of the present invention;

FIG. 4 is an explanatory diagram illustrating a field intensity distribution of 77 GHz that is a second harmonic signal according to Embodiment 2 of the present invention;

FIG. 5 is an explanatory diagram illustrating impedance on a resonance circuit side at a frequency of the second harmonic signal and phase noise according to Embodiment 2 of the present invention;

FIG. 6 is a structural diagram illustrating a structure of a voltage controlled oscillator in which a bias circuit is disposed including a line having a line length of λ for the second harmonic and a high frequency shorting capacitance according to Embodiment 3 of the present invention;

FIG. 7 is a structural diagram illustrating a structure of a voltage controlled oscillator in which an LCR circuit is disposed to be a short circuit load for the second harmonic according to Embodiment 4 of the present invention;

FIG. 8 is a structural diagram illustrating a structure of a voltage controlled oscillator in which a waveguide circuit is disposed to be a short circuit load for the second harmonic according to Embodiment 4 of the present invention;

FIG. 9 is a structural diagram illustrating a structure of a voltage controlled oscillator in which an open-end stub is disposed to be a short circuit load for the second harmonic according to Embodiment 5 of the present invention;

FIG. 10 is a structural diagram illustrating another structure of a voltage controlled oscillator in which an open-end stub is disposed to be a short circuit load for the second harmonic according to Embodiment 5 of the present invention;

FIG. 11 is a structural diagram illustrating still another structure of a voltage controlled oscillator in which an open-end stub and an short-end stub are disposed to be short circuit loads for the second harmonic according to Embodiment 5 of the present invention; and

FIG. 12 is a structural diagram illustrating a structure of a high frequency wireless device equipped with the voltage controlled oscillator according to any one of Embodiments 1 to 5.

### DETAILED DESCRIPTION OF THE PREFERRED EMBODIMENTS

### Embodiment 1

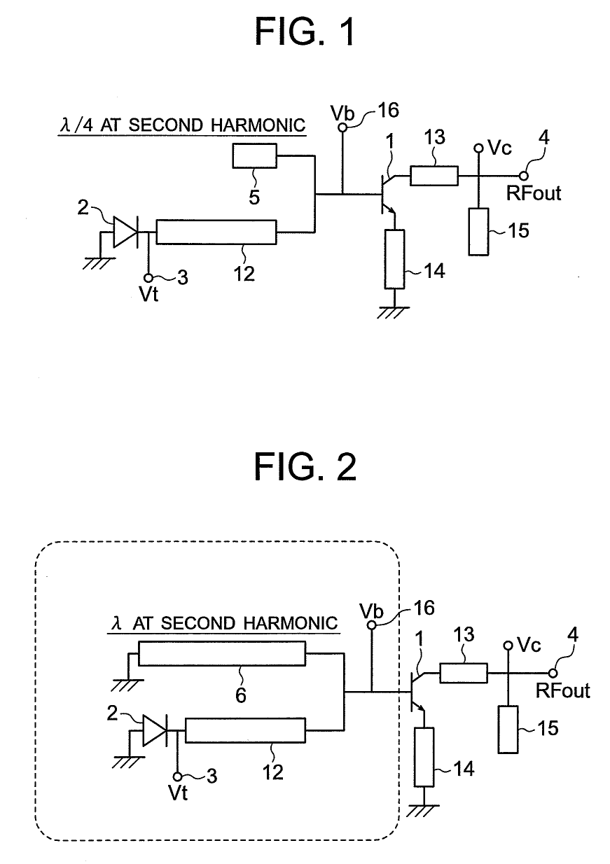

FIG. 1 is a structural diagram illustrating a structure of a VCO according to Embodiment 1 of the present invention. FIG. 1 illustrates a VCO having a serial positive feedback structure, which is a harmonic extraction oscillator in which an electric signal having a frequency that is an integral fraction of a desired frequency (i.e., fundamental wave signal) is oscillated so that a harmonic signal is delivered from an output terminal. Reference numeral 1 denotes a transistor; 2, a varactor; 3, a control voltage terminal; 4, a signal output terminal; 5, an open-end stub having a length corresponding to one quarter of the wavelength of the second harmonic signal; 12 and 13, lines; 14, an emitter line; 15, a fundamental wave reflection stub; and 16, a bias voltage terminal. The varactor 2, the line 12, and the control voltage terminal 3 constitute a variable resonator made up of a voltage variable capacitance component of the varactor 2 and an inductance component of the line 12. Changing a control voltage Vt to be applied to the control voltage terminal 3 enables the output frequency to be varied. The open-end stub 5 is connected in parallel to the variable resonator. The emitter line 14 is connected between the emitter of the transistor 1 and the ground. The fundamental wave reflection stub 15 is an open-end stub having a length corresponding to one fourth of the wavelength of the fundamental wave oscillating inside the circuit, for instance, and is connected to the line 13 attached to the output side of the transistor as illustrated in FIG. 1.

This structure of the VCO circuit is an MMIC, for instance, and it may also be realized by using a microwave integrated circuit (MIC) or discrete elements. Its substrate may be made of a material such as gallium arsenide (GaAs), gallium nitride (GaN), indium phosphide (InP), Si or the like.

The material of the transistor 1 is not limited, and silicon, gallium arsenide, gallium nitride or the like can be used. The structure of the transistor 1 is also not limited, and a bipolar transistor, a field effect transistor, a high electron mobility transistor or the like can be used. It can be a vacuum tube.

Next, operations are explained. A noise signal such as thermal noise inside the circuit is supplied to the transistor 1, which amplifies the noise signal. Then, the noise signal is fed back to the base of the transistor 1 from the emitter line 14 of the transistor 1 or reflected back from the fundamental wave reflection stub 15 via the line 13 and the transistor 1 and is supplied to the transistor 1 again to be amplified. Thus, oscillation of the fundamental wave frequency occurs inside the VCO, but the transistor 1 also generates harmonic signals having frequencies of twice, three times, and so on of the fundamental wave frequency (second harmonic signal, third harmonic signal, and so on). Since the fundamental wave reflection stub 15 is open for the second harmonic signal, the second harmonic signal is directed to the output terminal 4 and is delivered to the outside of the oscillator. Since the fundamental wave signal does not propagate to the output side farther from the fundamental wave reflection stub 15, it is not delivered to the outside of the oscillator.

If these harmonic signals propagate to the control voltage terminal 4 and make the control voltage Vt fluctuate, the output frequency fluctuates without intention. In other words, stability of the output frequency is lost and phase noise is increased. In order to suppress this fluctuation of the control voltage Vt, the open-end stub 5 is added between the transistor 1 and the line 12 so that the fundamental wave signal can pass therethrough while the harmonic signal is absorbed. This open-end stub 5 disables the harmonic signal to propagate to the control voltage terminal 3. In contrast, the fundamental wave signal can propagate to the varactor 2, and hence the oscillation frequency can be changed by changing the control voltage Vt externally so as to change capacitance of the varactor 2.

In this embodiment, since the open-end stub 5 has the length corresponding to one quarter of the wavelength of the second harmonic signal, the open-end stub 5 has a load that is neither a short circuit nor an open circuit for the fundamental wave frequency. Therefore, the fundamental wave signal fed back from the emitter line 14 of the transistor 1 or reflected back from the fundamental wave reflection stub 15 propagates to both the open-end stub 5 and the varactor 2. Thus, a resonator made up of a plurality of stubs for the fundamental wave is structured so that a high Q value can be realized for the fundamental wave. In this case, since the fundamental wave and the harmonic have a relationship of 6 dB/oct in the oscillator, phase noise can be reduced in both the fundamental wave and the harmonic. In contrast, the open-end stub 5 has a short circuit load for the second harmonic frequency, and hence the second harmonic signal propagates to the open-end stub 5 entirely and thus does not propagate to the varactor 2. Therefore, fluctuation of the control voltage Vt due to the second harmonic signal can be controlled, and the phase noise generated in the variable resonance circuit having the varactor 2 is reduced. In addition, electric field fluctuation due to the second harmonic signal is not generated at a connection node of the open-end stub 5. Therefore, fluctuation of a base voltage of the transistor 1 due to the second harmonic signal can be suppressed, and further the phase noise is reduced. Thus, a VCO with low phase noise can be realized.

Although the line length of the open-end stub 5 is one quarter of the wavelength of the second harmonic signal as an example in FIG. 1, it may be one quarter of the wavelength of the second harmonic signal plus an integral multiple of a half wavelength of the second harmonic signal. In other words, when the wavelength of the second harmonic signal is represented by λ, the line length can be a length defined by Expression (1) below (odd multiple of one quarter of the wavelength of the second harmonic signal). The open-end stub corresponding to the length defined by Expression (1) has a short circuit load for the harmonic while it has a load that is neither a short circuit nor an open circuit for the fundamental wave.

$$( 2 n = 1 ) \frac{λ}{4} ( n = 1 , 2 , … ) \qquad ( 1 )$$

In addition, it is not necessary to set the length of the open-end stub 5 strictly to be the length defined by Expression (1), but the length may have an error of approximately ±λ/16. It is because this range of error can be expected sufficiently to obtain the effect of suppressing the phase noise within the range of about 0.8 to 1.4 dB drop, as compared with the phase noise in the case where the length is set strictly according to Expression (1), with reference to a result of calculation of the level of the phase noise for the load impedance of the second harmonic on the resonance circuit side.

In this embodiment, the harmonic signal is the second harmonic signal. However, if a third harmonic signal, a fourth harmonic signal or the like is a dominant factor of deteriorating the phase noise, it is possible to use the open-end stub having the line length satisfying Expression (1) for the wavelength λ of the third harmonic signal, the fourth harmonic signal or the like so that the short circuit load is formed for the third harmonic frequency, the forth harmonic frequency or the like. In this case too, the effect of suppressing the phase noise can be expected even if the ±λ/16 error is included.

Although the example illustrated in FIG. 1 includes only one open-end stub 5 connected in parallel to the variable resonator, this structure is not a limitation. It is possible to connect two or more open-end stubs 5 in parallel to the variable resonator.

As described above, in this embodiment, at least one open-end stub is connected in parallel to the variable resonator, and a length of the open-end stub is smaller than or equal to an odd multiple of one quarter of the wavelength of a harmonic signal plus one sixteenth of the wavelength of the harmonic signal and is larger than or equal to an odd multiple of one quarter of the wavelength of the harmonic signal minus one sixteenth of the wavelength of the harmonic signal. Since the open-end stub 5 has a load that is neither a short circuit nor an open circuit for the fundamental wave frequency, and it has a short circuit load for the harmonic frequency, the fundamental wave signal can propagate to both the open-end stub 5 and the varactor 2 at the fundamental wave frequency. In other words, the resonator using a plurality of stubs is structured so that a high Q value can be realized. In contrast, the open-end stub 5 has a short circuit load for the harmonic frequency so that the harmonic signal propagates to the open-end stub 5 entirely. Therefore, the harmonic signal does not propagate to the varactor 2 so that the fluctuation of the control voltage Vt due to the harmonic signal can be suppressed. In addition, since the electric field fluctuation due to the harmonic signal is not generated at the connection node of the open-end stub 5, the fluctuation of the base voltage of the transistor 1 due to the harmonic signal can be suppressed. Thus, in this embodiment, the Q value for the fundamental wave frequency can be improved, and the fluctuation of the voltage to be applied to the varactor and the transistor due to the harmonic signal can be suppressed. As a result, a VCO having low phase noise can be realized.

Although FIG. 1 illustrates the example of the harmonic extraction oscillator having the fundamental wave reflection stub 15, even another type of fundamental wave oscillator delivering the fundamental wave without the fundamental wave reflection stub 15 can also realize the VCO having low phase noise similarly. In addition, if the variable resonator is connected to the emitter side or the collector side of the transistor 1 in the VCO, it is possible to realize the VCO having low phase noise similarly as long as the open-end stub 5 is connected in parallel to the variable resonator.

In this embodiment, even if the frequency of the fundamental wave signal or the harmonic signal is lower than 1 GHz, the same effect as described above can be obtained as long as the line length of the open-end stub 5 is set to be the length defined in Expression (1). Although the variable resonator is made up of the varactor 1 and the line 12 in the structure illustrated in FIG. 1, it is possible to adopt another structure in which it is made up of an LCR circuit including the varactor.

### Embodiment 2

FIG. 2 is a diagram illustrating a structure of a VCO according to Embodiment 2 of the present invention. In FIG. 2, reference numerals 1 to 4 and 12 to 16 denote the same elements as those of FIG. 1, and reference numeral 6 denotes an short-end stub having a length corresponding to the wavelength of a second harmonic signal. The stub that has the short circuit load for the second harmonic frequency and is connected to the variable resonator in parallel can be realized by using the short-end stub, too. It may have the line length defined by Expression (2) below (integral multiple of the wavelength of the second harmonic signal) for the wavelength λ of the second harmonic signal.

nλ(n=1, 2, . . . ) (2)

The short-end stub 6 having the line length defined by Expression (2) becomes a short circuit load also for the fundamental wave frequency at a low frequency lower than approximately 1 GHz. Therefore, the fundamental wave signal cannot propagate to the variable resonator including the varactor 2 so that the oscillation frequency cannot be varied. In contrast, as the frequency becomes higher, the line length defined by Expression (2) deviates from an integral multiple of the half wavelength of the fundamental wave signal due to a parasitic capacitance (C) component and a parasitic inductance (L) component included in the line of the short-end stub 6. Therefore, the short-end stub 6 having the line length defined by Expression (2) becomes to have a load that is neither a short circuit nor an open circuit for the fundamental wave frequency. Therefore, as for the VCO oscillating at a fundamental wave frequency of approximately 1 GHz or higher, it is possible to use the short-end stub 6 having the line length defined by Expression (2) instead of the open-end stub 5 in Embodiment 1.

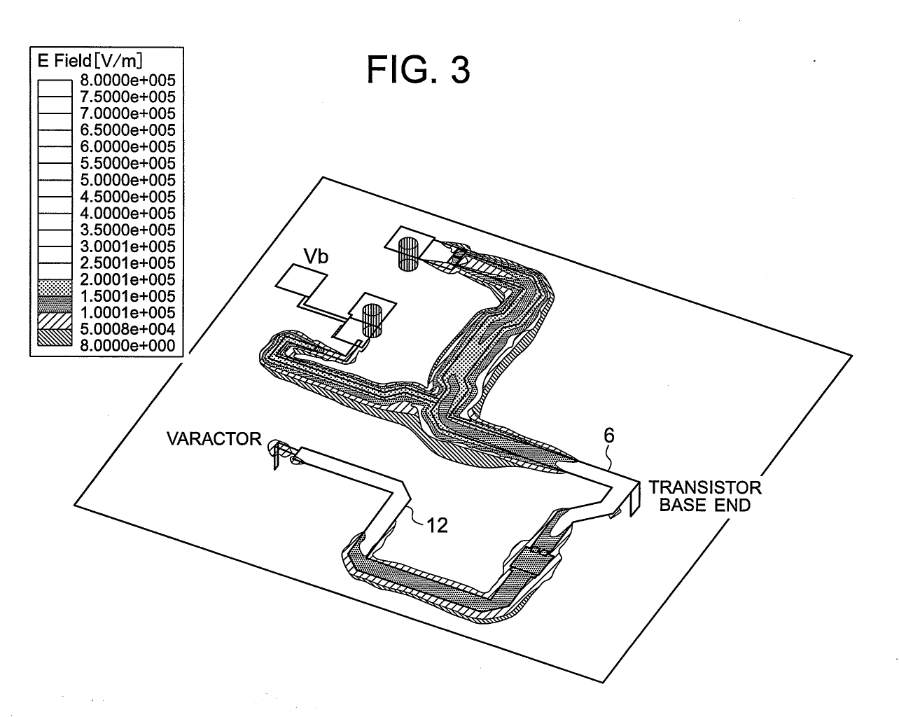

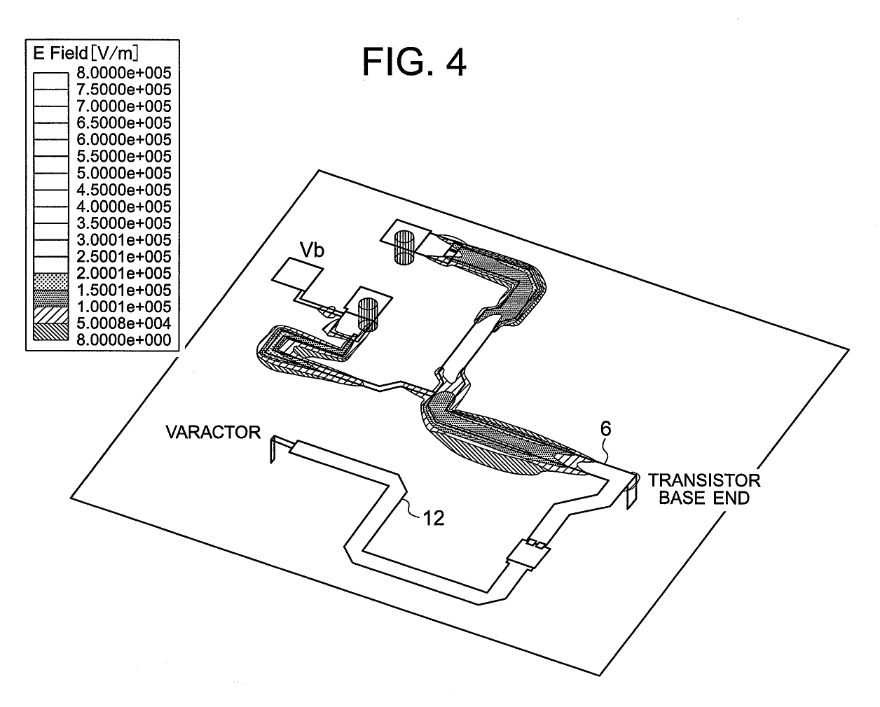

An operation principle of the VCO according to this embodiment is fundamentally the same as that of the VCO according to Embodiment 1. In order to verify the operation of the VCO according to this embodiment, FIGS. 3 and 4 illustrate examples of calculation results of electric field distribution inside the dotted line frame illustrated in FIG. 2 when the fundamental wave signal of 38 GHz and the second harmonic signal of 76 GHz are applied to the inside of the dotted line frame illustrated in FIG. 2 from the base terminal of the transistor, with the circuit structure being an MMIC. This calculation is performed in the arrangement where the bias voltage terminal 16 is connected to the middle of the short-end stub 6, but there is no substantial difference from the VCO illustrated in FIG. 2.

It is understood that the fundamental wave signal of 38 GHz propagates to both the short-end stub 6 and the varactor 2 from the electric field distribution as illustrated in FIG. 3. In contrast, it is understood that the second harmonic signal of 76 GHz propagates only to the short-end stub 6, but does not propagate to the varactor 2, from the electric field distribution as illustrated in FIG. 4. In addition, the electric field due to the second harmonic signal of 76 GHz becomes zero at the base terminal of the transistor. In other words, it is understood that the base voltage does not fluctuate.

Table 1 illustrates an example of calculation results of the phase noise of the VCO according to Embodiment 2. It is understood from Table 1 that there is no large difference between the output frequency in the case where the short-end stub 6 is disposed and the output frequency in the case where it is not disposed, and that the phase noise can be reduced by adding the shorting stub 6. In addition, it is possible to change the frequency by approximately 1 GHz by the voltage applied to the control voltage terminal 3 in both cases.

| | λ at second harmonic | | λ at second harmonic | |
|---|---|---|---|---|
| | without | | with | |
| | short-end stub 6 | | short-end stub 6 | |
| Output frequency | 77.80 | GHz | 77.70 | GHz |
| Phase noise | −107.8 | dBc/Hz | −115.9 | dBc/Hz |
| at 1 MHz offset | | | | |

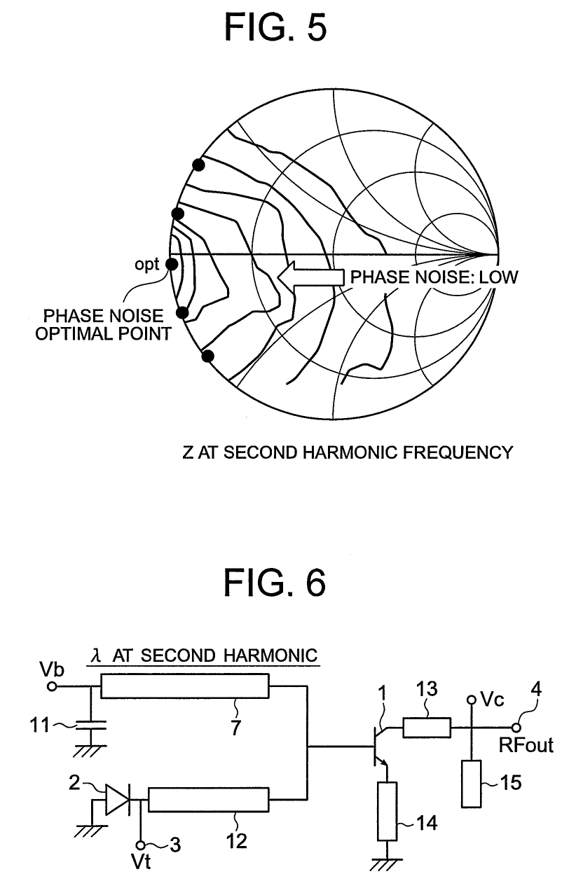

Note that in this embodiment too, similarly to Embodiment 1, it is not necessary to set the short-end stub 6 to have the exact length defined by Expression (2). The effect of suppressing the phase noise can be expected even if the ±λ/16 error is included. FIG. 5 illustrates the 50 ohm Smith Chart in which second harmonic load impedances of the resonance circuit side (variable resonance circuit and short-end stub 6) viewed from the base side of the transistor 1 short-end stub are dotted when the length of the short-end stub 6 is set to be λ−λ/16, λ−λ/32, λ, λ+λ/32, and λ+λ/16, respectively. In addition, a calculation result of a level of the phase noise for the second harmonic load impedance on the resonance circuit side is illustrated with contour lines of 0.2 dB step on the Smith Chart. If the length of the short-end stub 6 is λ, it becomes an optimal point where the phase noise is most reduced, i.e., the left end on the Smith Chart. As the length differs from the λ, the impedance of the resonance circuit side moves on the rim of the Smith Chart, whereby it is understood that the phase noise is being deteriorated. From the calculation result, it is understood that the phase noise is deteriorated from the optimal point by approximately 0.8 dB to 1.4 dB when the length of the short-end stub 6 becomes λ±λ/16. In this case too, the effect of reducing the phase noise can be expected sufficiently. Also as for Embodiment 1 in which the open-end stub 5 is used, a calculation result of a level of the phase noise for the second harmonic load impedance on the resonance circuit side is the same as that illustrated in FIG. 5.

In addition, it is possible to use the short-end stub having the line length that is adapted to satisfy Expression (2) for the wavelength of the third harmonic signal, the fourth harmonic signal or the like so that it becomes a short circuit load for the third harmonic frequency, the fourth harmonic frequency or the like. In this case too, the effect of reducing the phase noise can be expected even if the ±λ/16 error is included.

Although only one short-end stub 6 is connected in parallel to the variable resonator in the example illustrated in FIG. 2, this structure is not a limitation. It is possible to connect two or more short-end stubs 6 to the variable resonator in parallel. In addition, the end of the short-end stub 6 may be connected to the ground via a capacitor such as a metal-insulator-metal (MIM) capacitor to be a short circuit only for a high frequency.

In this embodiment, one or more short-end stubs are connected in parallel to the variable resonator, in which the length of the short-end stub is smaller than or equal to an integral multiple of the wavelength of a harmonic signal plus one sixteenth of the wavelength of the harmonic signal and is larger than or equal to an integral multiple of the wavelength of the harmonic signal minus one sixteenth of the wavelength of the harmonic signal. The short-end stub 6 has a load that is neither a short circuit nor an open circuit for the fundamental wave frequency while it has a short circuit load for the harmonic frequency. Therefore, the fundamental wave frequency propagates to both the short-end stub 6 and the varactor 2. In other words, a resonator using a plurality of stubs is constituted so that a high Q value can be realized. In contrast, the open-end stub 5 has a short circuit load for the harmonic frequency so that the harmonic signal propagates to the short-end stub 6 entirely. Therefore, the harmonic signal does not propagate to the varactor 2 so that the fluctuation of the control voltage Vt due to the harmonic signal can be suppressed. In addition, the electric field fluctuation due to the harmonic signal is not generated at the connection node of the short-end stub 6 so that the fluctuation of the base voltage of the transistor 1 due to the harmonic signal can be suppressed. Thus, in this embodiment too, similarly to Embodiment 1, a VCO having low phase noise can be realized.

Although an example of the harmonic extraction oscillator including the fundamental wave reflection stub 15 is illustrated in FIG. 2, even another type of fundamental wave oscillator delivering the fundamental wave without the fundamental wave reflection stub 15 can also realize the VCO having low phase noise similarly. In addition, if the variable resonator is connected to the emitter side or the collector side of the transistor 1 in the VCO, it is possible to realize the VCO having low phase noise similarly as long as the short-end stub 6 is connected in parallel to the variable resonator.

Although the variable resonator is made up of the varactor 1 and the line 12 in the structure illustrated in FIG. 2, it is possible to adopt another structure in which it is made up of an LCR circuit including the varactor.

### Embodiment 3

FIG. 6 is a diagram illustrating a structure of a VCO according to Embodiment 3 of the present invention. In FIG. 6, reference numerals 1 to 4 and 12 to 15 denote the same elements as those of FIG. 1, and reference numeral 7 denotes a bias circuit having a line length from the connection node to the short circuit portion for a high frequency via a capacitor 11 corresponding to the wavelength of the second harmonic signal.

The same effect as that of Embodiment 2 in which the short-end stub is added can be obtained by letting the bias circuit make a short circuit via the capacitor 11 at the portion separated from the connection node by a distance satisfying Expression (2), without newly adding the short-end stub 6 as described above in Embodiment 2.

Although the line length of the bias circuit 7 is adapted to be a length corresponding to the wavelength of the second harmonic signal according to the above-mentioned description, this structure is not a limitation. It is sufficient that the line length of the bias circuit 7 is a length corresponding to an integral multiple of the wavelength of the second harmonic signal. In addition, it may be a length corresponding to an integral multiple of the wavelength of the harmonic that is not limited to the second harmonic signal but can be a third or higher harmonic signal.

In addition, even if the line length of the bias circuit 7 includes the ±λ/16 error, the effect of reducing the phase noise can be expected.

Thus, according to this embodiment, the bias circuit is connected in parallel to the variable resonator, in which the line length from the connection node of the bias circuit to the ground connection portion via the capacitor is smaller than or equal to an integral multiple of the wavelength of a harmonic signal plus one sixteenth of the wavelength of the harmonic signal and is larger than or equal to an integral multiple of the wavelength of the harmonic signal minus one sixteenth of the wavelength of the harmonic signal. Therefore, similarly to Embodiment 2, a VCO having low phase noise can be realized in this embodiment, too.

### Embodiment 4

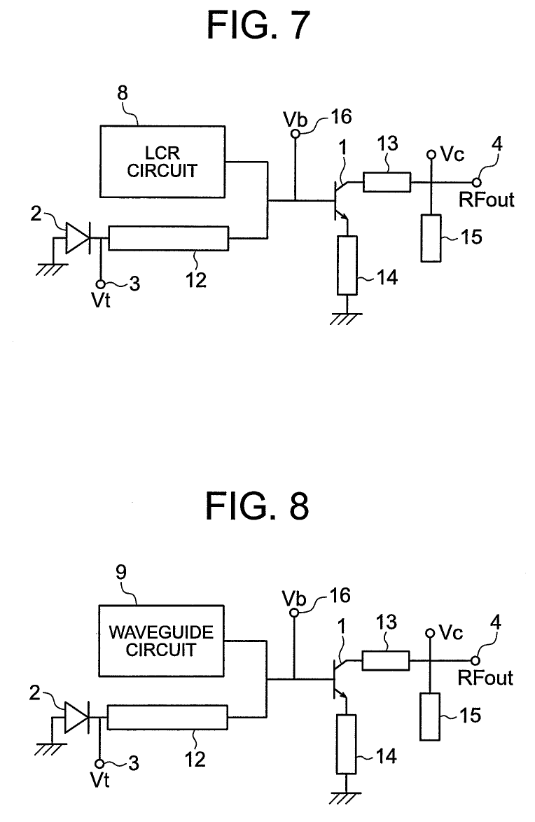

FIG. 7 is a diagram illustrating a structure of a VCO according to Embodiment 4 of the present invention. In FIG. 7, reference numerals 1 to 4 and 12 to 16 denote the same elements as those of FIG. 1, and reference numeral 8 denotes an LCR circuit having a short circuit load for the second harmonic frequency.

In addition, FIG. 8 is a diagram illustrating another example of a structure of the VCO according to Embodiment 4 of the present invention. In FIG. 8, reference numerals 1 to 4 and 12 to 16 denote the same elements as those of FIG. 1, and reference numeral 9 denotes a waveguide circuit having a short circuit load for the second harmonic frequency.

Note that each of the LCR circuit 8 and the waveguide circuit 9 has a short circuit load or a load close to the short circuit load, having e.g., an impedance within the range of −30 j ohms to +30 j ohms for the frequency of the harmonic signal. The load in this range corresponds to the range of λ±λ/16 of the short-end stub 6 illustrated in Embodiment 2 in the system of the characteristic impedance of 50 ohms. As understood from FIG. 5, deterioration of the phase noise is within the range of approximately 0.8 dB to 1.4 dB from the optimal point, and hence the effect of reducing the phase noise can be obtained. In addition, as understood from the Smith Chart illustrated in FIG. 5, even if the impedance has a real number component within the range of 0 to 15 ohms in addition to the above-mentioned imaginary number component, deterioration of the phase noise falls within the range of approximately 0.8 dB to 1.4 dB from the optimal point, and hence the effect of reducing the phase noise can be obtained.

It is sufficient that the circuit that is added in the above-mentioned Embodiment 1 or 2 should has a load that is neither a short circuit nor a open circuit for the fundamental wave frequency and a short circuit load for the harmonic frequency, and is not necessarily the line stub. Therefore, it is possible to use the LCR circuit 8 or the waveguide circuit 9 as described in this embodiment.

Thus, according to this embodiment, at least one LCR circuit 8 or waveguide circuit 9, which is not a short circuit for the fundamental frequency and has a load including a real number component within the range of 0 to 15 ohms and an imaginary number component within the range of −30 j to +30 j ohms for the frequency of the harmonic signal, is connected in parallel to the variable resonator. Therefore, similarly to the above-mentioned Embodiment 2 or 3, a VCO having low phase noise can be realized.

### Embodiment 5

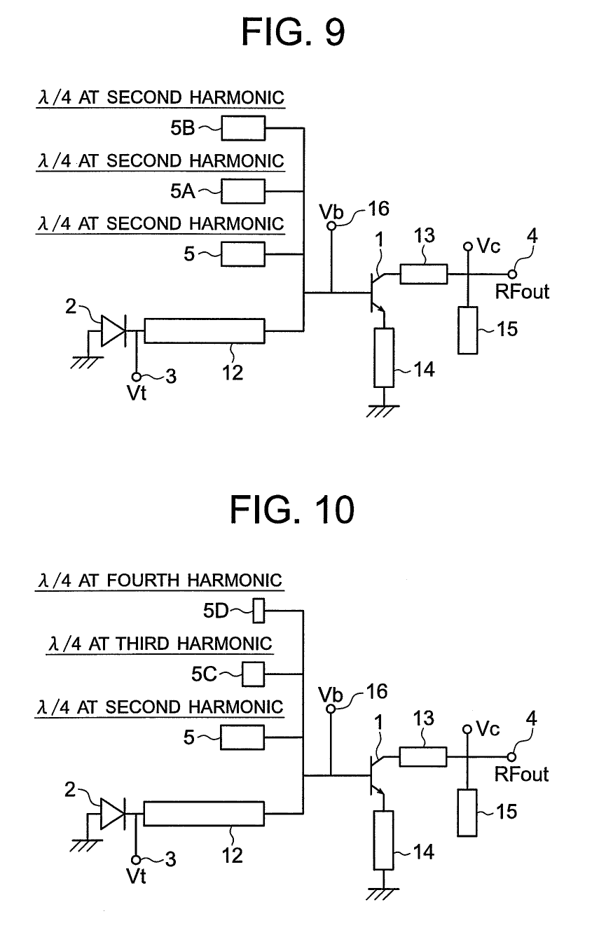

The circuit that is added in the above-mentioned Embodiment 1, 2 or 4 can also be a plurality of circuits as illustrated in FIG. 9. Although FIG. 9 illustrates an example of connecting the three open-end stubs 5, 5A, and 5B having the length corresponding to one quarter of the wavelength of the second harmonic signal illustrated in Embodiment 1, it is possible to connect the short-end stub 6 illustrated in Embodiment 2 or the LCR circuit 8 or the waveguide circuit 9 illustrated in Embodiment 4. In addition, the number thereof is not limited to three, but any appropriate number thereof may be connected.

In addition, if a plurality of orders of the harmonic signals become a factor of deteriorating the phase noise, it is possible to make the plurality of added circuits be short circuit loads for the different orders of the harmonic signals as illustrated in FIG. 10. In the example illustrated in FIG. 10, the open-end stub 5 having the length corresponding to one quarter of the wavelength of the second harmonic signal illustrated in Embodiment 1, the open-end stub 5C having the length corresponding to one quarter of the wavelength of the third harmonic signal and the open-end stub 5D having the length corresponding to one quarter of the wavelength of the fourth harmonic signal are added. However, this structure is merely an example and is not a limitation. An appropriate combination thereof should be selected based on a factor of deteriorating the phase noise.

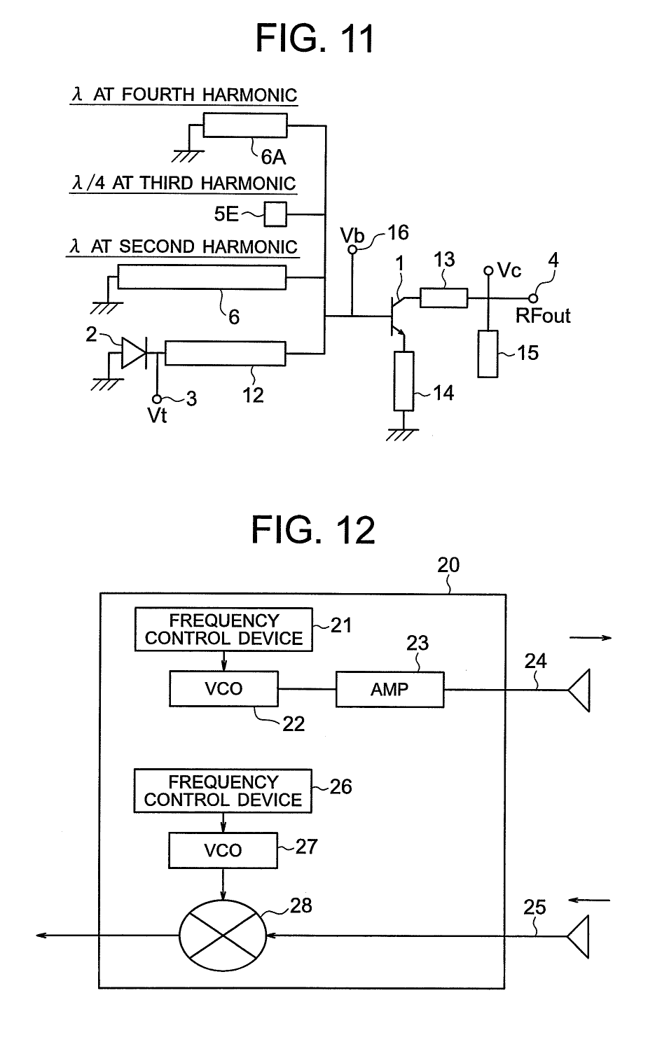

In addition, as illustrated in FIG. 11, the plurality of added circuits may be different from the short-end stub, the open-end stub, the LCR circuit, and the waveguide circuit. In the example illustrated in FIG. 11, the short-end stub 6A having the length corresponding to the wavelength of the fourth harmonic signal, the open-end stub 5E having the length corresponding to one quarter of the wavelength of the third harmonic signal, and the short-end stub 6 having the length corresponding to the wavelength of the second harmonic signal illustrated in Embodiment 2 are disposed, but this structure is not a limitation. As for this matter, an appropriate combination thereof should be selected based on a factor of deteriorating the phase noise.

Thus, also in this embodiment, a VCO having low phase noise can be realized similarly to the above-mentioned Embodiment 1, 2 or 4.

### Embodiment 6

FIG. 12 illustrates an example of a structure of a high frequency wireless device equipped with the voltage controlled oscillator according to anyone of Embodiments 1 to 5. A high frequency wireless device 20 is a radar device, a mobile phone or the like, which is an apparatus for performing transmission, reception or both of them using a microwave or a millimeter wave.

A voltage controlled oscillator 22 oscillates at a frequency based on a voltage signal from a frequency control device 21, an amplifier 23 amplifies the oscillation signal, and an output antenna 24 transmits a microwave or a millimeter wave. A reception antenna 25 receives the microwave or the millimeter wave. A mixer 28 performs frequency conversion of the oscillation signal delivered by a voltage controlled oscillator 27 based on the voltage signal of a frequency control device 26 and the reception signal from the reception antenna 25 so as to deliver a desired signal.

The transmission antenna 24 and the reception antenna 25 may be one unit. The frequency control devices 21 and 26, as well as the voltage controlled oscillators 22 and 27 may be one unit, respectively. In addition, it is possible to use the voltage controlled oscillator according to any one of Embodiments 1 to 5 to only one of the transmission portion and the reception portion.

When the high frequency wireless device uses the voltage controlled oscillator according to any one of Embodiments 1 to 5, a high quality microwave or millimeter wave with little phase noise can be transmitted. In addition, noise in the reception mode can be reduced.

1. A voltage controlled oscillator comprising:
a variable resonator; and
at least one open-end stub connected in parallel to the variable resonator, the open-end stub having a length
shorter than or equal to an odd multiple of one quarter of a wavelength of a harmonic signal plus one sixteenth of the wavelength of the harmonic signal, and
longer than or equal to an odd multiple of one quarter of the wavelength of the harmonic signal minus one sixteenth of the wavelength of the harmonic signal.

2. A voltage controlled oscillator comprising:
a variable resonator; and
at least one short-end stub connected in parallel to the variable resonator, the short-end stub having a length
shorter than or equal to an integer multiple of a wavelength of a harmonic signal plus one sixteenth of the wavelength of the harmonic signal, and
longer than or equal to an integer multiple of the wavelength of the harmonic signal minus one sixteenth of the wavelength of the harmonic signal.

3. A voltage controlled oscillator comprising:
a variable resonator; and
a bias circuit connected in parallel to the variable resonator so that line length from a connection node of the bias circuit to a ground connection portion via a capacitor is
shorter than or equal to an integer multiple of a wavelength of a harmonic signal plus one sixteenth of the wavelength of the harmonic signal, and
longer than or equal to an integer multiple of the wavelength of the harmonic signal minus one sixteenth of the wavelength of the harmonic signal.

4. A voltage controlled oscillator comprising:
a variable resonator; and
at least one LCR circuit or waveguide circuit connected in parallel to the variable resonator, the LCR circuit or waveguide circuit having a load that is not a short circuit for an oscillation frequency and includes an impedance having a real component within a range of 0 to 15 ohms and an imaginary component within a range of −30 j to +30 j ohms for a frequency of a harmonic signal.

5. A monolithic microwave integrated circuit (MMIC) comprising the voltage controlled oscillator according to claim 1.

6. A high frequency wireless device comprising the voltage controlled oscillator according to claim 4.

7. A monolithic microwave integrated circuit (MMIC) comprising the voltage controlled oscillator according to claim 2.

8. A monolithic microwave integrated circuit (MMIC) comprising the voltage controlled oscillator according to claim 3.

9. A monolithic microwave integrated circuit (MMIC) comprising the voltage controlled oscillator according to claim 4.

10. A high frequency wireless device comprising the voltage controlled oscillator according to claim 2.

11. A high frequency wireless device comprising the voltage controlled oscillator according to claim 3.

12. A high frequency wireless device comprising the voltage controlled oscillator according to claim 4.
